(19) United States
(12) Patent Application Publication
(10) Pub. No.: US 2008/0185651 A1
(43) Pub. Date: Aug. 7, 2008

(54) SOI type semiconductor device having a protection circuit

(75) Inventor: Masao Okihara, Tokyo (JP)

Correspondence Address: JUNICHI MIMURA;OKI AMERICA INC., 1101 14TH STREET, N.W., SUITE 555, WASHINGTON, DC, 20005, US

(73) Assignee: Oki Electric Industry Co., Ltd.

(21) Appl. No.: 12/007,318

(22) Filed: Jan. 9, 2008

(30) Foreign Application Priority Data
Feb. 1, 2007 (JP) 2007-022948
Mar. 27, 2007 (JP) 2007-081558

(51) Int. Cl. H01L 27/12

(52) U.S. Cl. 257/348; 257/E27.112

(57) ABSTRACT

An SOI type semiconductor device having a silicon substrate and a buried oxide layer formed on the silicon substrate includes an internal circuit formed in a first region having at least one FD type transistor having a SOI structure, the internal circuit performing a function of the semiconductor device and a protection circuit formed in a second region having at least one PD type transistor having a SOI structure, the protection circuit protecting the internal circuit from electro static damage.

### CROSS-REFERENCE TO RELATED APPLICATION

This application claims the priority benefit of Japanese Patent Application No. 2007-022948 filed on Feb. 1, 2007 and Japanese Patent Application No. 2007-081558, filed Mar. 27, 2007, the entire disclosures of which are incorporated herein by reference.

### BACKGROUND OF THE INVENTION

1. Field of the Invention

The invention relates to a semiconductor device including SOI-CMOS devices using SOI (Silicon On Insulator) substrate, specifically relates to a semiconductor device including a protection circuit, which protects the SOI-CMOS devices from ESD (Electro Static Damage).

2. Description of the Related Art

A semiconductor device having a protection circuit is disclosed in the following References.

Japanese Patent Reference 3,415,401

Japanese Patent Publication Reference H6-318702 A

Japanese Patent Publication Reference H8-125030 A

Japanese Patent Publication Reference 2002-313024 A

In the Japanese Patent Reference 3,415,401, it is disclosed that diodes are formed in a protection circuit area at the same time when CMOS transistors are formed in an internal circuit area. According to the Japanese Patent Reference 3,415,401, electrodes of the diodes in a protection circuit area are formed at the same time when gate electrodes of the CMOS transistors are formed, and diffusion layers of the diodes in the protection circuit area are formed by diffusing impurities at the same time when sources and drains of the CMOS transistors are formed.

In the Japanese Patent Publication Reference H6-318702 A, it is disclosed that an SOI layer formed in a protection circuit area is formed thicker than that an SOI layer formed in an area that internal circuit for requiring the high speed operation is formed, and in such an area, the fully-depletion is required. Further, the Japanese Patent Publication Reference H8-125030 A, it is disclosed that silicon material at a P/N junction in a protection device is amorphousized. Moreover, the Japanese Patent Publication Reference 2002-313024 A, it is disclosed that an ESD protection device is directly formed on a silicon substrate, which is acted as a supporting substrate.

Under a bulk-CMOS device, a P-type MOS transistor is electrically isolated from an N-type MOS transistor by a well-layer. To the contrary, under a SOI-CMOS device, a P-type MOS transistor is electrically and physically isolated from an N-type MOS transistor by a buried oxide layer formed on a silicon substrate and a LOCOS (LOCal Oxidation of Silicon) layer. Thus, the SOI (Silicon On Insulator) layer, which is a device operable region, is completely isolated by insulators. There are two types of the SIO layer. One is an FD (Fully depleted) SOI, and other is a PD (Partially depleted) SOI. The FD SOI includes a relatively thin SOI layer, which is generally less than 50 nm, and its body region under the channel in the thin SOI layer is fully depleted. On the other hand, the PD SOI includes a relatively thick SOI layer, which is generally more than 100 nm, and its body region under the channel in the thick SOI layer is partially depleted. Thus, the body region at its bottom under the channel in the thick SOI is not depleted. Compared with the PD SOI, since carriers generated under the operation of the devices are hard to be stored in the body region, the substrate floating effect is hard to be occurred, the operation under the low voltage and the low power consumption can be expected in the FD SOI.

However, when the internal circuit is formed with the transistors having the FD SOI structure, the protection circuit for protecting the internal circuit from the ESD is also generally formed with the transistors having the FD SOI structure because of the difficulty of manufacturing processes and some restrictions on its processes.

For example, a protection transistor used in the protection circuit is required to protect the internal circuit from the envisaged maximum surge current by flowing it to the conductive line connected to the ground terminal or the power supply terminal promptly. Thus, such a protection transistor should have functions of a current drive performance and of a responsive characteristic for flowing the envisaged maximum surge completely as a protection transistor performance, and thus, the width of the gate of the protection transistor should be formed for matching up to such requirements.

Specifically, a parasitic transistor is formed as a result of forming the protection transistor in a SOI wafer. The existence of the parasitic transistor holds the key to the performance of the protection transistor. The parasitic transistor is formed at the bottom of the protection transistor, and the parasitic transistor turned on locally in advance to the operation of the protection circuit on which the parasitic transistor is parasitic, by depending on the amount of the remaining carrier in the channel of the protection circuit. The surge current may be concentrated in the parasitic transistor so that the protection circuit can not flow the concentrated surge current completely to the conductive line connected to the ground terminal or the power supply terminal. As a result, the internal circuit may not be perfected from the ESD.

On the other hand, in the case that the protection transistor having a large gate width is formed, no parasitic transistors are formed at the bottom at all, theoretically. However, some parasitic transistors are actually formed locally in the protection circuit, and the surge current may be concentrated in the accidentally formed parasitic transistor. As a result, the protection circuit on which the parasitic transistor is parasitic is destroyed. Thus, it is desired to eliminate of forming parasitic transistors completely or control the formation of the parasitic transistors.

### SUMMARY OF THE INVENTION

An objective of the invention is to solve the above-described problem and to provide a semiconductor device having a protection circuit for protecting the internal circuit from the electro static damage.

The objective is achieved by an SOI type semiconductor device having a silicon substrate and a buried oxide layer formed on the silicon substrate including an internal circuit formed in a first region having at least one FD type transistor having a SOI structure, the internal circuit performing a function of the semiconductor device and a protection circuit formed in a second region having at least one PD type transistor having a SOI structure, the protection circuit protecting the internal circuit from electro static damage.

### BRIEF DESCRIPTION OF THE DRAWINGS

The invention will be more particularly described with reference to the accompanying drawings, in which:

FIG. 1 is a cross sectional view of a semiconductor device, according to the first embodiment;

FIG. 2 is a circuit diagram equivalent to the semiconductor device of FIG. 1;

FIG. 3A˜FIG. 3C are cross sectional views illustrating processing steps for manufacturing the semiconductor device shown in FIG. 1;

FIG. 4 is a sequential line graph showing a result of the device simulation performed to the to the semiconductor device of FIG. 1;

FIG. 5 is a cross sectional view of a semiconductor device, according to the second embodiment;

FIG. 6 is a cross sectional view illustrating a processing step for manufacturing the semiconductor device shown in FIG. 5;

FIG. 7 is an explanatory cross sectional view of a protection circuit of a semiconductor device, according to the second embodiment;

FIG. 8 is a circuit diagram equivalent to a semiconductor device, according to the third embodiment;

FIG. 9 is an comparison circuit diagram for explaining the physical operations of a protection transistor of the semiconductor device of the third embodiment and a protection transistor of the related art; and

FIG. 10A˜FIG. 10E are cross sectional views illustrating processing steps for manufacturing a protection transistor of the semiconductor device of the third embodiment.

### DETAILED DESCRIPTION OF THE PREFERRED EMBODIMENTS

The preferred embodiment of the invention is explained together with drawings as follows. In each drawing, the same reference numbers designate the same or similar components.

### The First Embodiment

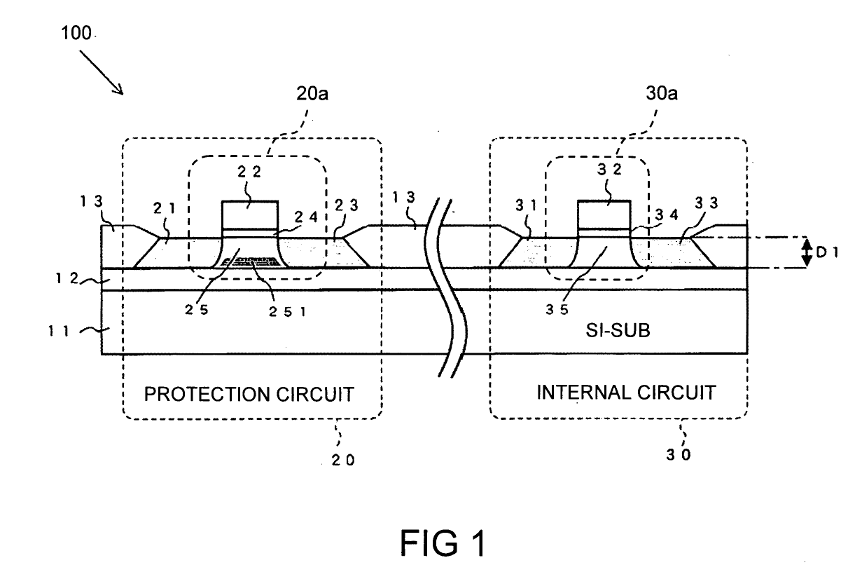

FIG. 1 is a cross sectional view of a semiconductor device 100, according to the first embodiment. The semiconductor device 100 includes at least one protection circuit 20 and at least one internal circuit 30.

The semiconductor device 100 includes an SOI (Silicon-On-Insulator) structure. According to the semiconductor device 100, a Buried OXidation layer (BOX layer) 12 is formed on a silicon substrate 11, which is acted as a supporting substrate, and an active silicon layer (SIO layer) is formed on the Box layer 12. Source regions and drain regions 21, 31, 23, 33 are formed in the SOI layer. According to such a structure, since a parasitic capacitance formed between source/drain regions and the silicon substrate 11 becomes smaller, a high speed operation with low power consumption can be expected. Further, since each device is electrically isolated completely by the BOX layer, a latch-up phenomenon may not be occurred. On the other hand, since the insulating layer exists underneath the thin silicon layer in semiconductor device having the SOI structure, when high voltage is induced by static electricity at the thin silicon layer, the internal circuit is easily destroyed by the ESD (Electro Static Damage).

The protection circuit 20 protects the internal circuit 30 from such ESD. Although the Internal circuit 30 includes a plurality of transistors having CMOS structures and other desired circuit elements based on the functions of the internal circuit 30, one internal transistor 30a in the internal circuit 30 is illustrated in FIG. 1 for the sake of brevity of explanation. Moreover, although the protection circuit 20 includes one or more protection transistors 20a or 20b and other circuit elements, one protection transistor 20a in the protection circuit 20 is illustrated in FIG. 1 for the sake of brevity of explanation. However, the structure of the protection transistor 20b is the same as that of the protection transistor 20a.

The internal transistor 30a in the internal circuit 30 includes a source region 31 and a drain region 33, which are formed by ion-implantation into the SOI layer being formed on the silicon substrate 11, a body region 35, which is sandwiched by the source and drain regions 31 and 33, in the SOI layer, and a gate region 32, which is formed of Poly-silicon and is formed on a gate oxide layer 34 being formed on the body region 35. Thus, the internal transistor 30a illustrated in FIG. 1 is a MOS FET. The MOS FET can be either a P-type MOS FET or an N-type MOS FET. The thickness D1 of the SOI layer is 0.05 μm. Field oxide layers 13, which isolate each transistor, are formed at the side of each of the source/drain regions 31 and 33. The field oxide layers 13 are formed by a thermal treatment to the SOI layer. The gate, source and drain regions 32, 31, and 33 are connected to external devices through contact metal layers, respectively.

The protection transistor 20a in the internal circuit 20 includes a source region 21 and a drain region 23, which are formed by ion-implantation into the SOI layer being formed on the silicon substrate 11, a body region 25, which is sandwiched by the source and drain regions 21 and 23, in the SOI layer, and a gate region 22, which is formed of Poly-silicon and is formed on a gate oxide layer 24 being formed on the body region 25. Thus, the protection transistor 20a illustrated in FIG. 1 is a MOS FET. The MOS FET can be either a P-type MOS FET or an N-type MOS FET. When the protection transistor 20a is formed of the N-type MOS FET, the source and the drain region 21 and 23 are formed of N-type as the second conductivity type, and the body region 25 is formed of P-type as the first conductivity type.

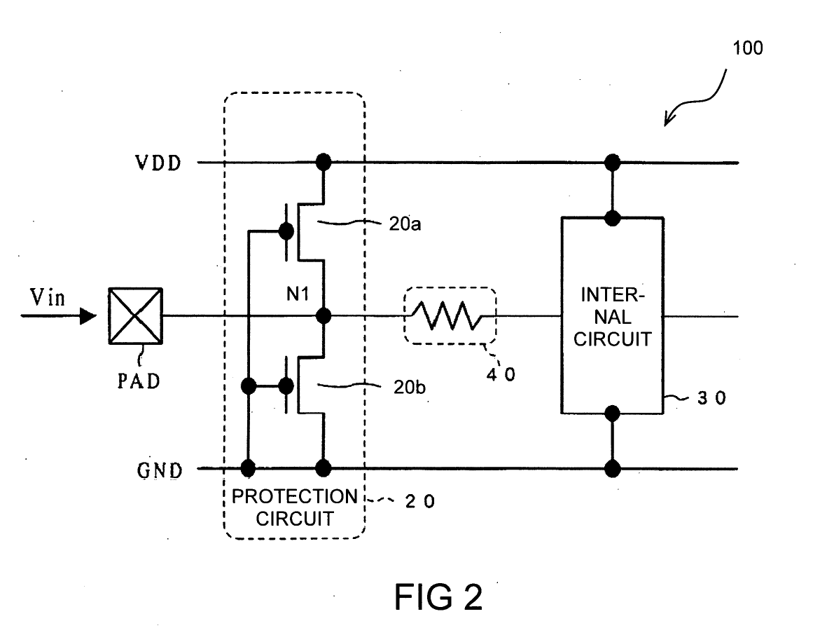

Since the SOI layer is formed to have an uniform thickness through the protection and internal circuits 20 and 30 in the first embodiment, the thickness D1 of the SOI layer in the protection circuit 20 is 0.05 μm, which is the same as that in the internal circuit 30. Field oxide layers 13, which isolate each transistor, are formed at the side of each of the source/drain regions 21 and 23. The field oxide layers 13 are formed by a thermal treatment to the SOI layer. The gate, source and drain regions 22, 21, and 23 are connected to the power supply voltage or the ground GND through contact metal layers, respectively as show in FIG. 2, which is explained below.

In the protection transistor, a highly doped region 251, which is one of the characteristics of the invention, is formed in the body region 25. According to forming the highly doped region 251, the protection transistor 20a in the protection circuit 20 is formed with the PD SOI while the internal transistor 30a in the internal circuit 30 is formed with the FD SOI. According to the structure described above, the body region 25 having a high channel impurity concentration, which is a highly doped region 251, is formed at the bottom of the SOI layer of the protection transistor 20a that is the location closer to the BOX layer than the middle location in the depth direction. Thus, since the depletion layer formed in the body region 25 is hard to be extended, the protection transistor 20a is formed with the PD SOI. Both of the protection transistor 20a and the internal transistor 30a may include an LDD (Lightly Doped Drain) region for suppressing the short channel effect. The LDD structure increases the current drive performance of the protection circuit 20 when the surge current is applied.

FIG. 2 is a circuit diagram equivalent to the semiconductor device of FIG. 1. The internal circuit 30 is connected to the power supply terminal VDD and the ground terminal GND, and the gates of internal CMOS transistors in the internal circuit 30 are commonly connected to an input terminal PAD via a protection resistor 44 wherein the input voltage Vin is applied to the input terminal PAD. The protection circuit 20 includes two NMOS protection transistors 20a and 20b whose gates are commonly connected to the ground terminal GND. The source of the NMOS protection transistors 20a is connected to the power supply terminal VDD and its drain is connected to the source of the NMOS protection transistors 20b whose drain is connected to the ground terminal GND.

A connection node N1 between the drain of the NMOS protection transistors 20a and the source of the NMOS protection transistors 20b is connected to the input terminal PAD and one end of the protection resistor 40. As described above, since the other end of the protection resistor 40 is connected to the internal circuit 30, the connection node N1 is connected to the internal circuit 30 via the protection resistor 40. For example, when the negative surge current is applied from the ground terminal GND, the negative surge current is flowed to the conductive line connected to the power supply terminal VDD by turning the NMOS protection transistors 20a and 20b on in order to avoid flowing the negative surge current into the internal circuit 30. Under this state, the NMOS protection transistors 20a and 20b are required to flow the negative surge current speedy and promptly, the NMOS protection transistors 20a and 20b should not only have a function of a current drive performance for flowing the envisaged maximum negative surge current completely, but also have a function of withstanding the envisaged maximum negative surge current.

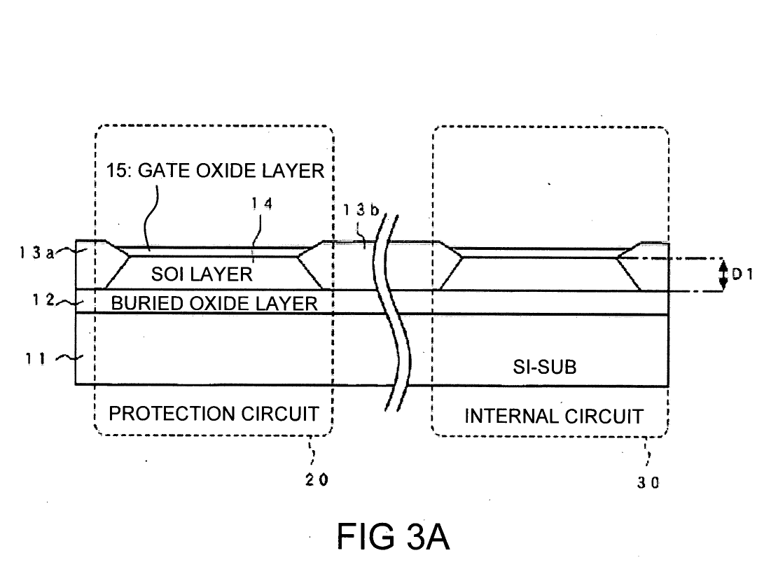

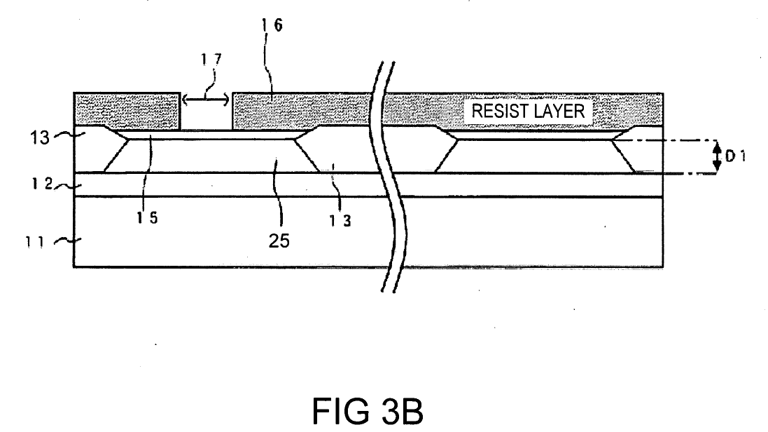

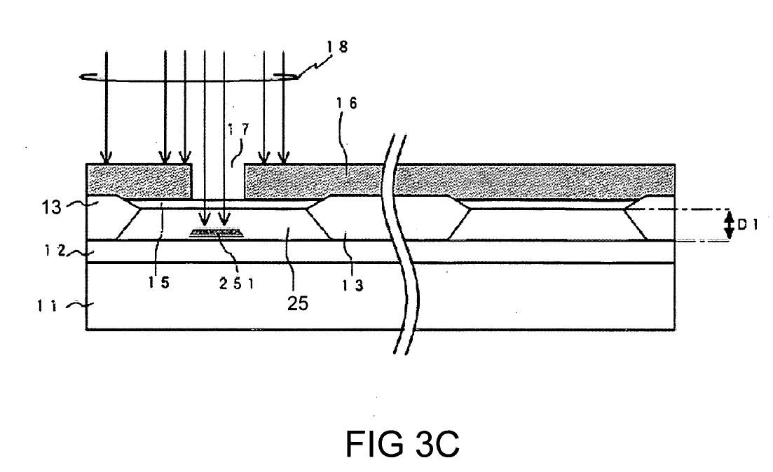

The process of the semiconductor device 100 shown in FIG. 1 is explained as follows with reference to FIG. 3A˜FIG. 3C. FIG. 3A˜FIG. 3C are cross sectional views illustrating processing steps for manufacturing the semiconductor device 100 shown in FIG. 1. As shown in FIG. 3A, a BOX layer 12 is formed on the Silicon substrate 11, and then the SOI layer 14 having the uniform thickness D1, which is around 0.05 μm, is formed on the BOX layer 12. A silicon nitride layer, which was patterned by the well-known photolithographic method, is formed on the SOI layer 14, and then the SOI layer is exposed to the thermal oxide condition, which is known as the LOCOS (local oxidation of Silicon) process, in order to form field oxide layers 13, which isolates the protection circuit 20 from the internal circuit 30. Then, a gate oxide film 15 is formed on the SOI layer 14 by the well-know thermal oxidation. Then, by the ion implantation method, the SOI layer 14 includes an area in which ion impurity is lightly doped, which is called the body region 25 shown in FIG. 1.

As shown in FIG. 3B, a resist layer 16 is formed on the entire surface. The resist layer 16 includes an opening in an area, which corresponds to a channel region of the protection transistor, which is sandwiched by the source and drain regions 21 and 23 shown in FIG. 1.

Then, as shown in FIG. 3C, highly concentrated impurity ions 18 are doped into the body region 25 through the opening 17 and the gate oxide film 15 underneath. This ion implantation is performed with high energy, such as 40 KeV, so that the project range Rp in average of the ion implantation can be set to the bottom location in the body region 25. Thus, by using the method of high energy ion implantation, the concentration of the channel region in the body region 25 can be set at high at the bottom. When the P-type MOS FET is used for the protection transistor, the conductivity type of the highly concentrated impurity ions 18 is P type. To the contrary, when the N-type MOS FET is used for the protection transistor, P-type impurity ions 18, such as Boron (B) or Boron difluoride (BF₂), are used. According to this step, the highly doped region 251 is formed at the bottom of the body region 25 located under the opening 17.

Then, a poly silicon layer is formed on the gate oxide film 15 by the well known low pressure CVD (Chemical Vapor Deposition) method, and the gate electrodes 22 and 32, each of which has a 0.15 μm gate length, are formed by etching the poly silicon. Then, the self-aligned source regions 21 and 31 and the self-aligned drain regions 23 and 33 are formed by using gate oxide layer 24 and resist layer as a mask in the body regions 25 and 35 by implanting ions whose conductivity type is different from that of the impurity ions 18. As a result, the semiconductor device 100 shown in FIG. 1 can be obtained.

As described above, by adding two methods, which are the photolithographic method and the highly concentrated impurity ion implantation method, on the process of forming the FD type transistors in the internal circuit 30, the PF type transistors can be easily formed in the protection circuit 20 only. Here, the ion implantation with the highly concentrated impurity ions to the bottom of the body region 25 may be performed before forming the gate oxide film 15.

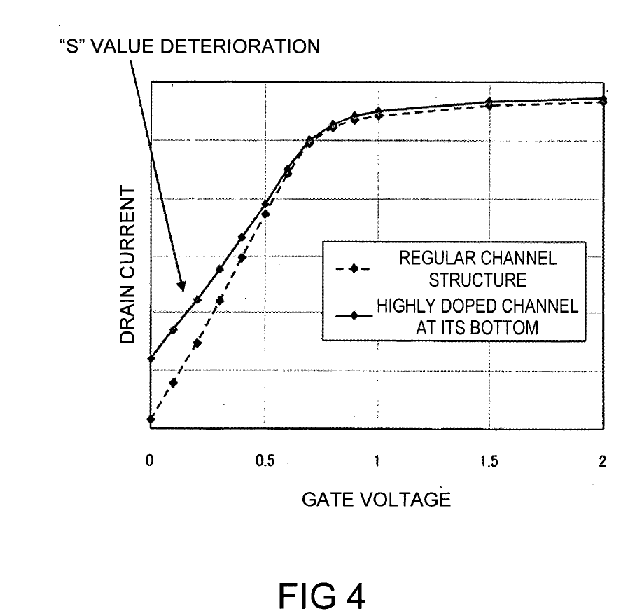

FIG. 4 is a sequential line graph showing a result of the device simulation performed to the to the semiconductor device of FIG. 1. In FIG. 4, the gate voltage (V) is measured along the horizontal axis and the drain current is measured along the vertical axis. In FIG. 4, two sequential lines are compared. When the body region for N channel transistor 20a or 20b in the protection circuit 20 is formed by implanting ions of BF² as a channel impurity, one sequential broken line represents a method that the body region is formed to have a regular channel by controlling the ion implantation energy with 15 keV, and one sequential solid line represents a method that the body region is formed to have a highly doped channel by controlling the ion implantation energy between 15 keV and 40 keV.

It is clear from FIG. 4, by forming the highly doped region for the channel region at the bottom of the body region, an S value in the solid line is deteriorated so that the protection transistor performs the PD operation. The S values is the gate voltage Vg at the sub-threshold area that changes the drain current Ids by one digit with the drain voltage held constant, and is represented by the following equation.

S=Vg/log(Ids)

For example, where S=60 mV/dec, the drain current Ids is increased with one digit by increasing the gate voltage Vg with 60 mV

According to the semiconductor device 100 of the first embodiment, holes exist in the he highly doped region 251, which is not the depletion layer, because the highly concentrated impurity ions is doped at the bottom of the body region 25. Thus, when the surge current is applied to the silicon substrate 11, the parasitic transistor, which is formed at the bottom of the protection transistor 20a or 20b, cannot be turned on if the holes in the body region are not moved to the source region. It is known that it takes few m.sec to move the holes to the source region. The channel of the protection transistor 20a or 20b performs an appropriate operation within that time period. Thus, the semiconductor device shown in FIG. 1 of the first embodiment has a protection circuit performance, which has no local operation caused by the parasitic transistors.

Furthermore, the semiconductor device of the first embodiment, two types of the transistors that are the FD type and the PD types formed in the internal circuit 30 and the protection circuit 20 are not formed in the quit different processes. In other words, by adding two methods, which are the photolithography and the highly concentrated impurity ion implantation, on the process of forming FD type transistors in the internal circuit 30, the PF type transistors can be easily formed in the protection circuit 20 only. Thus, the semiconductor device having two types of the transistors can be manufactured without increasing large numbers of the process steps and increasing process difficulties.

Since the protection circuit 20 is only operable in the occasion that the surge current is flowed, the protection transistor having the PD SOI will not influence to the entire operation of the semiconductor device 100.

### The Second Embodiment

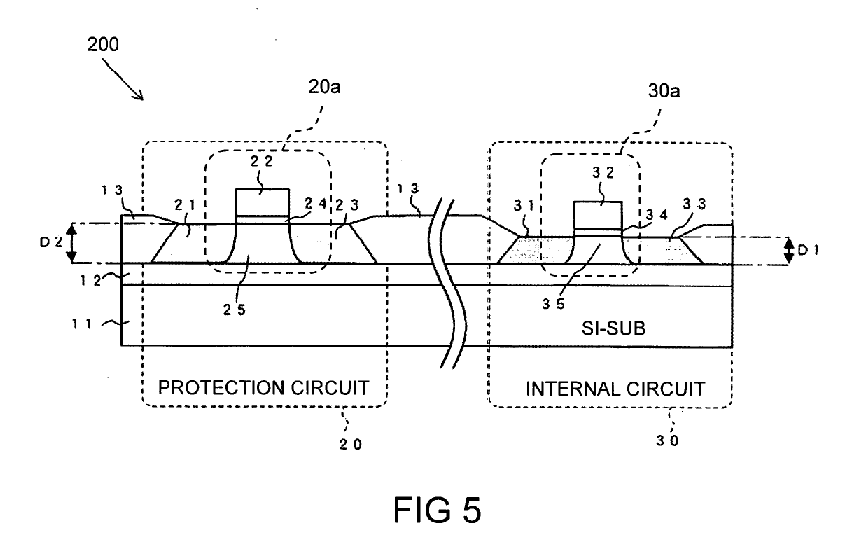

FIG. 5 is a cross sectional view of a semiconductor device 200, according to the second embodiment. In FIG. 5, the same reference numbers designate the same or similar components used in FIG. 11n the semiconductor device 200, as well as the semiconductor device 100 of the first embodiment, the internal transistor 30a in the internal circuit 30 includes the FD SOI. However, a SOI layer of a protection transistor 20a or 20b in a protection circuit in the second embodiment is formed thicker than that of the internal transistor 30a. The difference is explained in detail as follows.

The semiconductor device 200 includes at least one protection circuit 20 and at least one internal circuit 30. The semiconductor device 200 includes an SOI structure. According to the semiconductor device 200, a Box layer 12 is formed on a silicon substrate 11, which is acted as a supporting substrate, and an active silicon layer (the SIO layer) is formed on the Box layer 12. Source regions and Drain regions 21, 31, 23, 33 are formed in the SOI layer.

The protection circuit 20 protects the internal circuit 30 from such ESD. Although the Internal circuit 30 includes a plurality of transistors having CMOS structures and other desired circuit elements based on the functions of the internal circuit 30, one internal transistor 30a in the internal circuit 30 is illustrated in FIG. 5 for the sake of brevity of explanation. Moreover, although the protection circuit 20 includes one or more protection transistors and other circuit elements, one protection transistor 20a in the protection circuit 20 is illustrated in FIG. 5 for the sake of brevity of explanation. However, the structure of the protection transistor 20b is the same as that of the protection transistor 20a.

The internal transistor 30a in the internal circuit 30 includes a source region 31 and a drain region 33, which are formed by ion-implantation into the SOI layer being formed on the silicon substrate 11, a body region 35, which is sandwiched by the source and drain regions 31 and 33, in the SOI layer, and a gate region 32, which is formed of Poly-silicon and is formed on a gate oxide layer 34 being formed on the body region 35. Thus, the internal transistor 30a illustrated in FIG. 5 is a MOS FET. The protection transistor 20a in the internal circuit 20 includes a source region 21 and a drain region 23, which are formed by ion-implantation into the SOI layer being formed on the silicon substrate 11, a body region 25, which is sandwiched by the source and drain regions 21 and 23, in the SOI layer, and a gate region 22, which is formed of Poly-silicon and is formed on a gate oxide layer 24 being formed on the body region 25. Thus, the protection transistor 20a illustrated in FIG. 5 is a MOS FET.

One of the most important characteristics is the thickness of the SOI layer. As shown in FIG. 5, the thickness D2 of the SOI layer in the protection transistor 20a is greater than the thickness D1 of the SOI layer in the internal transistor 30a. While the thickness D1 is set at 0.05 μm, the thickness D2 is set as more than 0.1 μm. According to the structure described above, the depletion layer formed in the body region 25 is not extended to its bottom completely so that the protection transistor 20a performs the PD type operation.

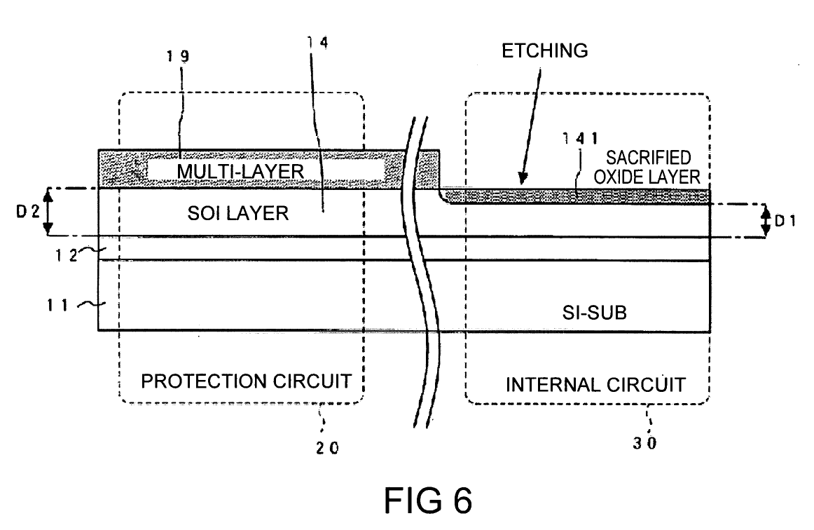

The process of the semiconductor device 200 shown in FIG. 5 is explained as follows with reference to FIG. 6. FIG. 6 is a cross sectional view illustrating a processing step for manufacturing the semiconductor device shown in FIG. 5. A multi-layer 19 formed of a silicon oxide layer and a silicon nitride layer as the anti-oxidation layer is formed on the SOI layer 14. Then the multi-layer 19 in an area other than the area of the protection circuit 20 is removed by the photolithography and the etching process. As the result, the SOI layer in the area other than the area of the protection circuit 20 is exposed. Then, the exposed SOI layer 14 is oxidized. As a result, a sacrificed oxidation layer 141 is formed at the surface of the SOI layer 14. Then, the multi layer 19 and the sacrificed oxidation layer 141 are removed by the well known wet etching process. As a result, the thickness D2 of the SOI layer in the area other than protection circuit becomes thinner, while the thickness D1 of the SOI layer in the protection circuit remains the same. After these processes were performed, the field oxide layers 13, gate oxide layers 24, 34, gate regions 22 and 32 and source and drain regions 21, 31, 23 and 33 are formed by the same process disclosed in the first embodiment. As a result, the semiconductor device 200 shown in FIG. 5 can be obtained.

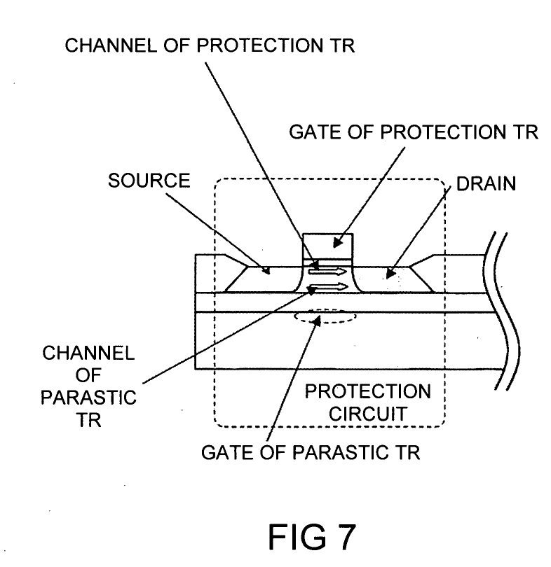

According to the semiconductor device 200 of the second embodiment, the regions, which are not the depletion layers, remain in the SOI layer at its bottom because of the thickness of the body region 25 so that the holes exist in these regions. FIG. 7 is an explanatory cross sectional view of showing the physical operation of the protection circuit 20a of a semiconductor device when the surge current is applied to the silicon substrate 11. When the surge current is applied to the silicon substrate 11, the parasitic transistor, which is formed at the bottom of the protection transistor 20a, cannot be turned on if the holes in the body region are not moved to the source region. It is known that it takes few m.sec to move the holes to the source region. The channel of the protection transistor 20a performs an appropriate operation within that time period. Thus, the semiconductor device 200 shown in FIG. 5 of the second embodiment has a protection circuit performance, which has no local operation caused by the parasitic transistors. As well as the first embodiment, since the protection circuit 20 is only operable in the occasion that the surge current is flowed, the protection transistor having the PD SOI will not influence to the entire operation of the semiconductor device 200.

According to the semiconductor device 200 in the second embodiment, Wile the internal circuit 30 is formed with the transistors with the FD SOI structure, the protection circuit 20 for protecting the internal circuit 30 from the ESD is formed with the transistors with the FD SOI structure. Thus, the functions of the internal circuit 30 are not limited to have the specific characteristics so that the internal circuit can be used for general-purpose CPUs or mobile devices.

### The Third Embodiment

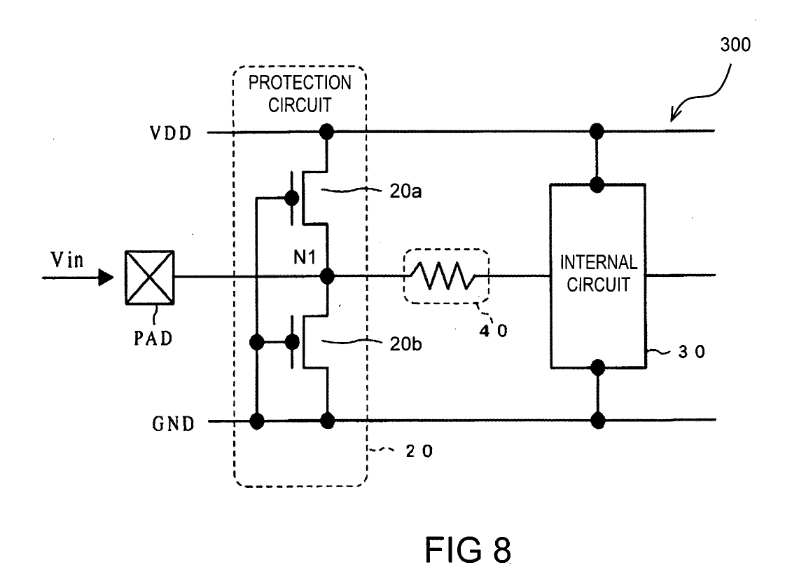

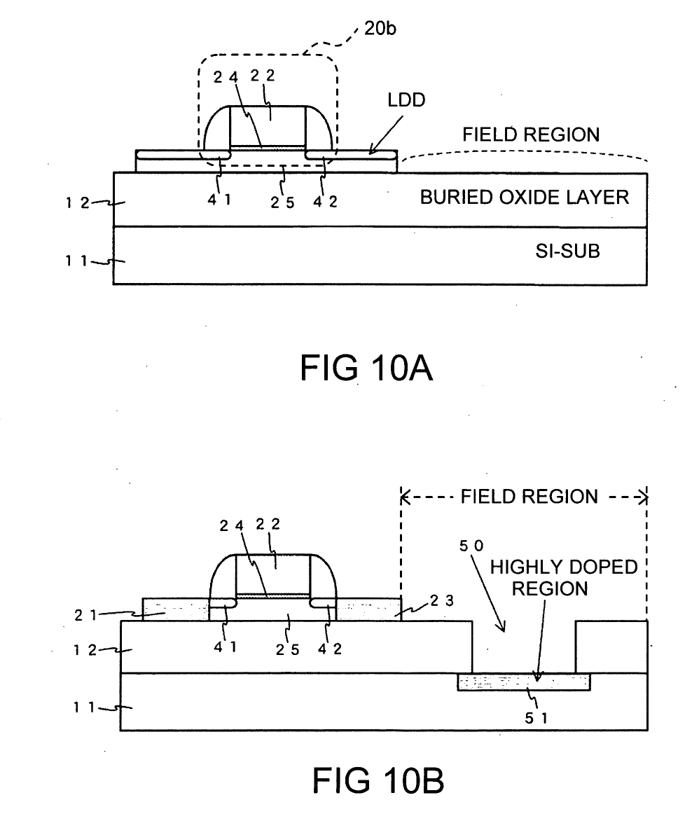

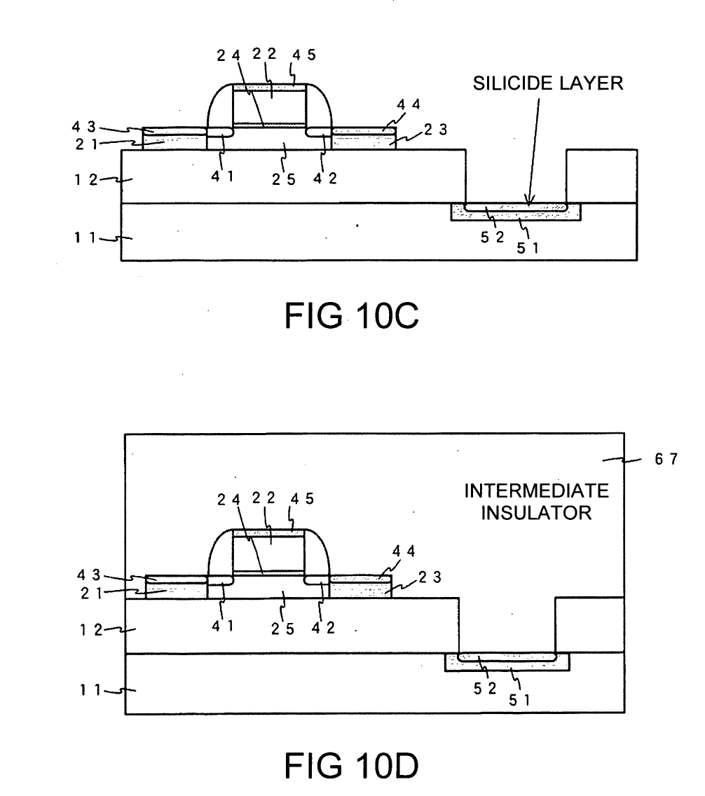

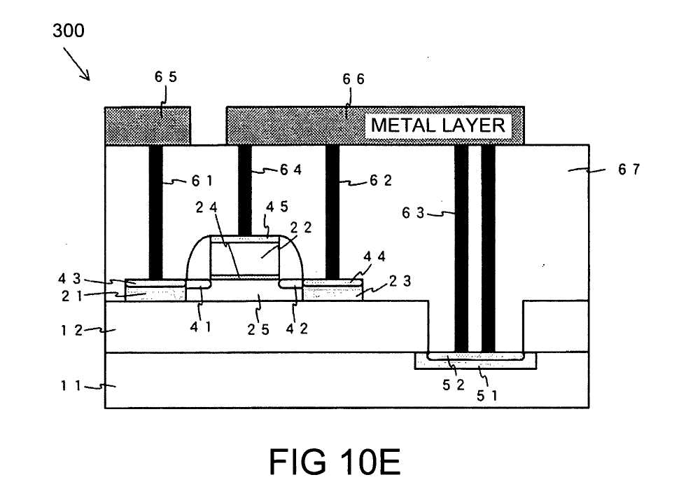

FIG. 8 is a circuit diagram equivalent to a semiconductor device 300 shown in FIG. 10E, according to the third embodiment. In FIG. 8, the same reference numbers designate the same or similar components used in FIG. 2. The semiconductor device 300 includes at least one protection circuit 20 and at least one internal circuit 30 as a functional circuit performing desired functions. The semiconductor device 300 includes an SOI structure.

The internal circuit 30 is connected to the power supply terminal VDD and the ground terminal GND, and the gates of internal CMOS transistors in an internal circuit 30 are commonly connected to an input terminal PAD via a protection resistor 44 wherein the input voltage Vin is applied to the input terminal PAD.

The protection circuit 20 includes two NMOS protection transistors 20a and 20b whose gates are commonly connected to the ground terminal GND. The source of the NMOS protection transistors 20a is connected to the power supply terminal VDD and its drain is connected to the source of the NMOS protection transistors 20b whose drain is connected to the ground terminal GND.

A connection node N1 between the drain of the NMOS protection transistors 20a and the source of the NMOS protection transistors 20b is connected to the input terminal PAD and one end of the protection resistor 40. As described above, since the other end of the protection resistor 40 is connected to the internal circuit 30, the connection node N1 is connected to the internal circuit 30 via the protection resistor 40. For example, when the negative surge current is applied from the ground terminal GND, the negative surge current is flowed to the conductive line connected to the power supply terminal VDD by turning the NMOS protection transistors 20a and 20b on in order to avoid flowing the negative surge current into the internal circuit 30.

The semiconductor device 300 further includes a substrate line SUB, which is connected to the ground terminal GND electrically. The ground terminal GND is commonly connected to the gate and the source of the protection transistor 20b and to the gate of the protection transistor 20a. The electrical connection between the silicon substrate and the substrate line SUB is made by a metal wiring via a substrate contact, which penetrates a buried oxide layer. The processes of forming the substrate line SUB and its electrical contact are explained below with reference to FIGS. 10A˜E. Although the protection transistors 20a and 20b are formed of NMOS transistors in the third embodiment, they may be replaced to PMOS transistors.

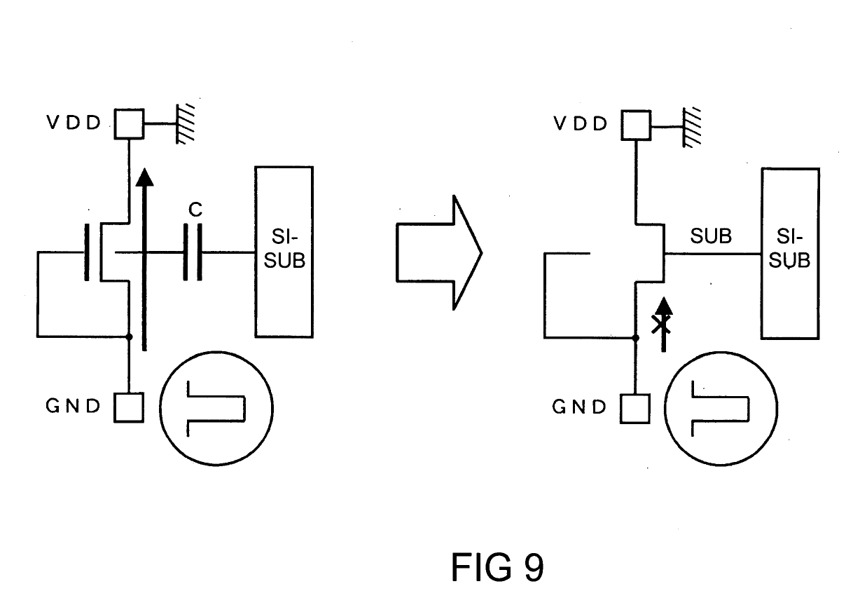

FIG. 9 is a comparison circuit diagram for explaining the physical operations of the protection transistor of the semiconductor device 300 shown in FIG. 8 and a protection transistor of the related art. According to the left drawing in FIG. 8, the protection transistor in the related art is floating against the silicon substrate. This is meant that a capacitor C is formed between the protection transistor and the silicon substrate. Under this structure, when a surge voltage, whose electric potential is opposite to that for the protecting operation of the protection circuit, is applied to the ground terminal GND, the parasitic channel of the parasitic transistor formed at the bottom of the body region because of the SOI structure turns on since the electric potential of the silicon substrate, which corresponds to the gate of the parasitic transistor, is not the same as that of the source region of the protection transistor. On the other hand, according to the right drawing in FIG. 8, the protection transistor of the semiconductor device 300 shown in FIG. 8 is connected to the silicon substrate via the substrate line SUB. Under this structure, when the surge voltage is applied to the silicon substrate, the parasitic transistor may not turn on because the electric potential of the silicon substrate is the same as that of the source region of the protection transistor. Thus, according to the protection transistor shown in the right drawing in FIG. 9, it is possible to suppress the ESD phenomenon of the protection circuit caused by the parasitic transistors,

FIG. 10A˜FIG. 10E are cross sectional views illustrating processing steps for manufacturing the protection transistor 20b of the semiconductor device of the third embodiment. The process of the protection transistor 20b of the semiconductor device 300 shown in FIG. 8 is explained as follows with reference to FIG. 10A˜FIG. 10E.

As shown in FIG. 10A, the protection transistor 20b is formed on an SOI wafer, which includes the silicon substrate 11 and the BOX layer 12 formed on the silicon substrate 11. The protection transistor 20b is formed by the well known CMOS process. In FIG. 10A, side walls are form on the both side of the gate region 22. For more details, the protection transistor 20b includes the body region 25 formed on the BOX layer 12 and the silicon substrate 11, which acts as the supporting substrate, the gate region 22 disposed on a gate oxide layer 24 formed the body region 25 and the LDD region 41 and 42, which is self-aligned to the gate region 22.

As shown in FIG. 10B, an opening 50 is formed to the BOX layer 12 in the field region, which is adjacent to the body region 25. As the result, the silicon substrate 11 is exposed by the opening 50, which is formed by the photolithography and the etching process. Then, a highly doped ion implantation treatment is performed to the silicon substrate 11 through the opening 50 and to the body region for the source and drain regions 21 and 23 by using an unillustrated appropriate resist mask. According to this treatment, a highly doped region 51 is formed at the surface of the silicon substrate 11 in the opening 50 together with the source and drain region 21 and 23. When the protection transistors are formed with PMOS transistor, a p-type impurity is used as the dopant for the highly doped region 51.

As shown in FIG. 10C, after the RTA (Rapid Thermal Anneal) treatment is performed to activate the impurity in the highly doped region 51 and in the source and drain region 21 and 23, a gate silicide layer 45 at the surface of the gate region 22, a source silicide layer 43 at the surface of the source region 21 and a drain silicide layer 44 at the surface of the drain region 22 by the well-known silicidation process. During the silicidation process, a silicide layer 52 may be formed in the highly doped region 51. The substrate line SUB illustrated in FIG. 8 is formed of the silicide layer 52 and the highly doped region 51. The silicide layers 43, 44, 45 and 52 are formed of low resistance material.

As shown in FIG. 10D, an intermediate layer 67 is formed on the entire surface of the protection circuit, and the surface of the intermediate layer 67 is then planarized by the CMP (Chemical Mechanical Polishing) process.

Finally, as shown in FIG. 10E, contact holes, contact metal wires and metal layers are formed. For more details, the contact holes, which reach to the source silicide layer 43, the drain silicide layer 44, the gate silicide layer 45 and the silicide layer 52, are formed in the intermediate layer 67, and the holes are filled with the contact metal wires 61, 62, 64 and 63. The metal layers 65 and 66 are formed on the planarized intermediated layer 67. The source silicide layer 43 is connected to the metal layer 65, which is connected to the drain region of the transistor 20a, by the contact metal wire 61. The drain silicide layer 44, the gate silicide layer 45 and the silicide layer 52 are connected to the metal layer 66 by the contact metal layers 62, 64 and 63, respectively. As shown in FIG. 10E, a number of the contact metal wire 63 may be plural.

According to the semiconductor device of the third embodiment, it is possible to contact the source of the protection transistor 20b having the SOI structure to the silicon substrate 11 without any additional thermal treatments to the general CMOS process. Thus, since the characteristics of the protection transistor will not be influenced by forming the above described structure, which connect the source of the protection transistor 20b the substrate line SUB, the protection circuit 20 having a desired protection performance that only a parasitic transistors do not turn on can be obtained.

While the invention has been described with reference to illustrative embodiments, this description is not intended to be construed in a limiting sense. Thus, shapes, size and physical relationship of each component are roughly illustrated so the scope of the invention should not be construed to be limited to them. Further, to clarify the components of the invention, hatching is partially omitted in the cross-sectional views. Moreover, the numerical description in the embodiment described above is one of the preferred examples in the preferred embodiment so that the scope of the invention should not be construed to limit to them.

Various other modifications of the illustrated embodiment will be apparent to those skilled in the art on reference to this description. Therefore, the appended claims are intended to cover any such modifications or embodiments as fall within the true scope of the invention.

What I claim is:

1. A Silicon-On-Insulator type semiconductor device having a silicon substrate and a buried oxide layer formed on the silicon substrate, comprising:
an internal circuit formed in a first region having at least one Fully-Depletion type transistor having a Silicon-On-Insulator structure, the internal circuit performing a function of the semiconductor device; and
a protection circuit formed in a second region having at least one Partially-Depletion type transistor having the Silicon-On-Insulator structure, the protection circuit protecting the internal circuit from electro static damage.

2. A Silicon-On-Insulator type semiconductor device as claimed in claim 1, wherein the Partially-Depletion type transistor includes a lightly doped body region surrounded by its gate, its source, its drain and the buried oxide layer, and the body region includes a highly doped region at its bottom, which is adjacent to the buried oxide layer.

3. A Silicon-On-Insulator type semiconductor device as claimed in claim 2, wherein the lightly doped body region of the Partially-Depletion type transistor is a first lightly doped body region having a first thickness, wherein the Fully-Depletion type transistor includes a second lightly doped body region having a second thickness surrounded by its gate, its source, its drain and the buried oxide layer, and wherein the first and the second thicknesses are the substantially the same.

4. A Silicon-On-Insulator type semiconductor device as claimed in claim 2, wherein the Partially-Depletion type transistor includes an LDD region.

5. A Silicon-On-Insulator type semiconductor device as claimed in claim 2, wherein the Partially-Depletion type transistor is a first Partially-Depletion type transistor of a certain conductivity type, the protection circuit further comparing:
a second Partially-Depletion type transistor of the same conductivity type of the first Partially-Depletion type transistor,
wherein the gates of the first and second Partially-Depletion type transistors and the drain of the first Partially-Depletion type transistor are commonly connected to a first power supply voltage, the source of the first Partially-Depletion type transistor and the drain of the second Partially-Depletion type transistor are connected to each other via a node, which is connected to the internal circuit, and the source of the second Partially-Depletion type transistor is connected to the second power supply voltage.

6. A Silicon-On-Insulator type semiconductor device as claimed in claim 1, wherein the Partially-Depletion type transistor includes a first body region surrounded by its gate, its source, its drain and the buried oxide layer, the Fully-Depletion type transistor includes a second body region surrounded by its gate, its source, its drain and the buried oxide layer, and wherein the first body region is thicker than the second body region.

7. A Silicon-On-Insulator type semiconductor device as claimed in claim 6, wherein the first body region is twice as thick as the second body region

8. A Silicon-On-Insulator type semiconductor device as claimed in claim 6, wherein the Partially-Depletion type transistor includes an LDD region.

9. A Silicon-On-Insulator type semiconductor device as claimed in claim 6, wherein the Partially-Depletion type transistor is a first Partially-Depletion type transistor of a certain conductivity type, the protection circuit further comparing:
a second Partially-Depletion type transistor of the same conductivity type of the first Partially-Depletion type transistor,
wherein the gates of the first and second Partially-Depletion type transistors and the drain of the first Partially-Depletion type transistor are commonly connected to a first power supply voltage, the source of the first Partially-Depletion type transistor and the drain of the second Partially-Depletion type transistor are connected to each other via a node, which is connected to the internal circuit, and the source of the second Partially-Depletion type transistor is connected to the second power supply voltage.

10. A Silicon-On-Insulator type semiconductor device having a silicon substrate and a buried oxide layer formed on the silicon substrate, comprising:
A first conductive line connected to a first power supply voltage;
a second conductive line connected to a second power supply voltage;
a substrate line electrically connected to the silicon substrate;
an internal circuit formed in a first region having at least one transistor having a Silicon-On-Insulator structure, the internal circuit performing a function of the semiconductor device; and
a protection circuit formed in a second region having at least one transistor having the Silicon-On-Insulator structure, the protection circuit protecting the internal circuit from electro static damage, and the gate and the source of the transistor being commonly connected to the substrate line.

11. A Silicon-On-Insulator type semiconductor device as claimed in claim 10, wherein the substrate line is formed on the surface of the silicon substrate in a field region, which electrically isolates the protection circuit from the internal circuit.

12. A Silicon-On-Insulator type semiconductor device as claimed in claim 10, wherein substrate line is formed of multi-layers, which includes a highly doped region formed on the surface of the silicon substrate and a silicide layer formed in the highly doped region.

13. A Silicon-On-Insulator type semiconductor device as claimed in claim 10, wherein the transistor is the protection circuit is a first transistor of a certain conductivity type, the protection circuit further comparing:
a second transistor of the same conductivity type of the first transistor, whose gate is connected to the first transistor,
wherein the source of the first transistor and the drain of the second transistor are connected to each other via a node, which is connected to the internal circuit, and the source of the second transistor is connected to the second power supply voltage.
